(19) United States
(12) Patent Application Publication
(10) Pub. No.: US 2007/0230138 A1
(43) Pub. Date: Oct. 4, 2007

(54) Heat sink and fan unit

(75) Inventors: Takaya Otsuki, Kyoto (JP); Takamasa Yamashita, Kyoto (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: NIDEC CORPORATION, Kyoto (JP)

(21) Appl. No.: 11/730,622

(22) Filed: Apr. 3, 2007

(30) Foreign Application Priority Data
Apr. 4, 2006 (JP) 2006-103686

(51) Int. Cl. H05K 7/20

(52) U.S. Cl. 361/719

(57) ABSTRACT

A heat sink and fan unit including a heat sink and a cooling fan is provided. The heat sink has a plurality of heat-dissipating fins. The cooling fan is arranged to create a current of a cooling air toward the heat sink, and includes a supporting leg extending toward the heat sink. The supporting leg is screwed to the heat sink with a screw inserted into the supporting leg toward the heat sink, thereby securing the cooling fan to the heat sink.

### BACKGROUND OF THE INVENTION

1. Field of the Invention

The present invention relates to a structure for fastening a heat sink and a cooling fan to each other in a heat sink and fan unit which cools an object to be cooled such as an electronic part, e.g., MPU.

2. Description of the Related Art

MPU (Micro processing unit) carries out various operations for received data to output the result and works as a core of a computer. MPU is incorporated in a high-performance electronic device. In recent years, the amount of heat generated in MPU has continued to increase with a rapid clock increase of MPU. The heat generated in MPU may cause malfunction of MPU itself. Thus, a method for cooling MPU is extremely important.

For this reason, an electronic part generating heat such as MPU, which is mounted in a high-performance electronic device, is used with a heat sink and fan unit attached thereto. The heat sink and fan unit is formed by a combination of a heat sink including a plurality of heat-dissipating fins having as large surface area as possible and a cooling fan for generating a current of a cooling air toward the heat sink. The heat-dissipating fins are made of metal. The heat sink and fan unit is arranged in such a manner that the body of the heat sink is in direct contact with the electronic part to be cooled. The heat generated in MPU is conducted to the heat sink which is forcedly cooled by the cooling air sent by the cooling fan.

The heat sink and fan unit is formed by attaching and securing the cooling fan to the heat sink. There are various attaching and securing methods.

### SUMMARY OF THE INVENTION

According to a preferred embodiment of the present invention, a heat sink and fan unit includes a heat sink having a plurality of heat-dissipating fins and a cooling fan that generates a current of a cooling air toward the heat sink. The cooling fan includes a supporting leg extending toward the heat sink. The supporting leg is fastened to the heat sink with a screw inserted into the supporting leg toward the heat sink, to fasten the cooling fan to the heat sink.

In another preferred embodiment of the present invention, the supporting leg is provided at its top end with a through hole into which the screw is inserted toward the heat sink. The through hole includes a larger-diameter portion and a smaller-diameter portion that have a larger inner diameter and a smaller inner diameter, respectively. The larger-diameter portion is closer to the heat sink than the smaller-diameter portion. The screw includes an external thread portion, a head portion having a larger outer diameter than that of the external thread portion, and a cylindrical-column portion arranged between the external thread portion and the head portion and having no thread. The cylindrical-column portion has an outer diameter smaller than the smaller-diameter portion of the through hole. The external thread portion has an outer diameter between those of the smaller-diameter portion and the larger-diameter portion. The small-diameter portion of the through hole is arranged between the head portion and the external thread portion of the screw to prevent detachment of the screw when the cooling fan is detached from the heat sink.

Other features, elements, advantages and characteristics of the present invention will become more apparent from the following detailed description of preferred embodiments thereof with reference to the attached drawings.

### BRIEF DESCRIPTION OF THE DRAWINGS

FIG. 1 is a perspective view of a cooling fan and a heat sink according to a preferred embodiment of the present invention.

FIG. 2 is a perspective view of a heat sink and fan unit according to the preferred embodiment of the present invention.

FIG. 3 is a perspective view of a spacer and a securing hole formed in a base portion of the heat sink according to the preferred embodiment of the present invention.

FIG. 4 is a cross-sectional view of a fastening structure in which a supporting leg and the base portion are screwed to each other via the spacer according to the preferred embodiment of the present invention.

FIG. 5 is a side view of the heat sink and fan unit according to the preferred embodiment of the present invention, mounted on MPU.

FIG. 6 is a top view of the heat sink and fan unit according to the preferred embodiment of the present invention.

### DETAILED DESCRIPTION OF PREFERRED EMBODIMENTS

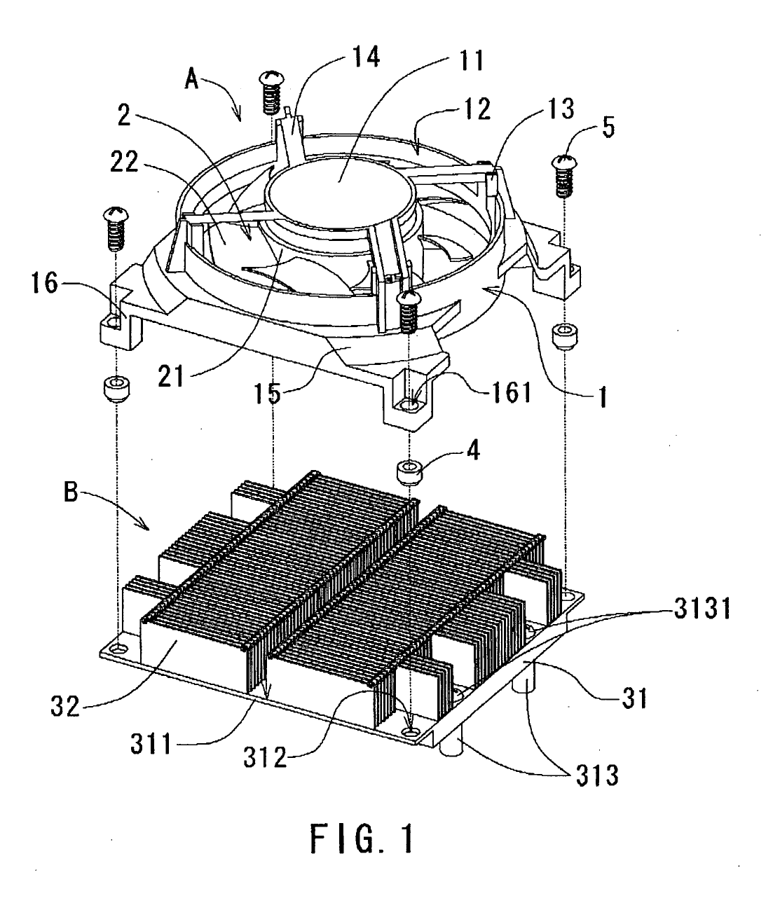

Referring to FIGS. 1 through 6, a preferred embodiment of the present invention will be described in detail. It should be noted that in the explanation of the present invention, when positional relationships among and orientations of the different components are described as being up/down or left/right, ultimately positional relationships and orientations that are in the drawings are indicated; positional relationships among and orientations of the components once having been assembled into an actual device are not indicated. Meanwhile, in the following description, an axial direction indicates a direction parallel to a rotation axis, and a radial direction indicates a direction perpendicular to the rotation axis.

### (1) Structure of Cooling Fan

FIG. 1 is a perspective view of a cooling fan A and a heat sink B according to a preferred embodiment of the present invention.

The cooling fan A includes an impeller 2 rotatable about a rotation axis. The impeller 2 is attached below a lower part of a hollow, approximately cylindrical housing cup 11 having a cover portion. The impeller 2 includes a hollow, approximately cylindrical cup 21 having a bottom portion, and a plurality of blades 22 arranged on an outer circumferential surface of the cup 21 at regular circumferential intervals. The blades 22 rotate about the rotation axis, thereby generating an airflow flowing downward in the axial direction.

In general, the airflow thus generated by the blades 22 spreads and is discharged radially outward by a centrifugal force acting on the airflow on or near surfaces of the blades 22. However, in order to improve a cooling performance of the heat sink B, it is necessary to maximize the amount of the airflow which is generated by the cooling fan A and sent to a central portion of the heat sink B. Thus, the cooling fan A is formed and arranged to make the airflow generated by the cooling fan A flow along the axial direction without spreading radially outward in this preferred embodiment. More specifically, the blades 22 are curved to be convex toward an upstream side in a rotation direction of the blades 22. With this configuration, even if a centrifugal force acts on air near the blades 22, the surfaces of the blades 22 apply a radially inward force to the air, so that the airflow hardly spreads radially outward.

A surrounding wall 12 surrounding the impeller 2 in the radial direction is arranged radially outside the impeller 2. Four supports 13 standing upward in the axial direction are provided at an axially upper end of the surrounding wall 12 at regular circumferential intervals. The number of supports 13 is not limited to four. A rib 14 extending inward in the radial direction is provided at an axially upper end of each support 13. The rib 14 is connected to the housing cup 11 at its radially inner end. In this manner, the housing cup 11 is supported by the four supports 13 and the four ribs 14.

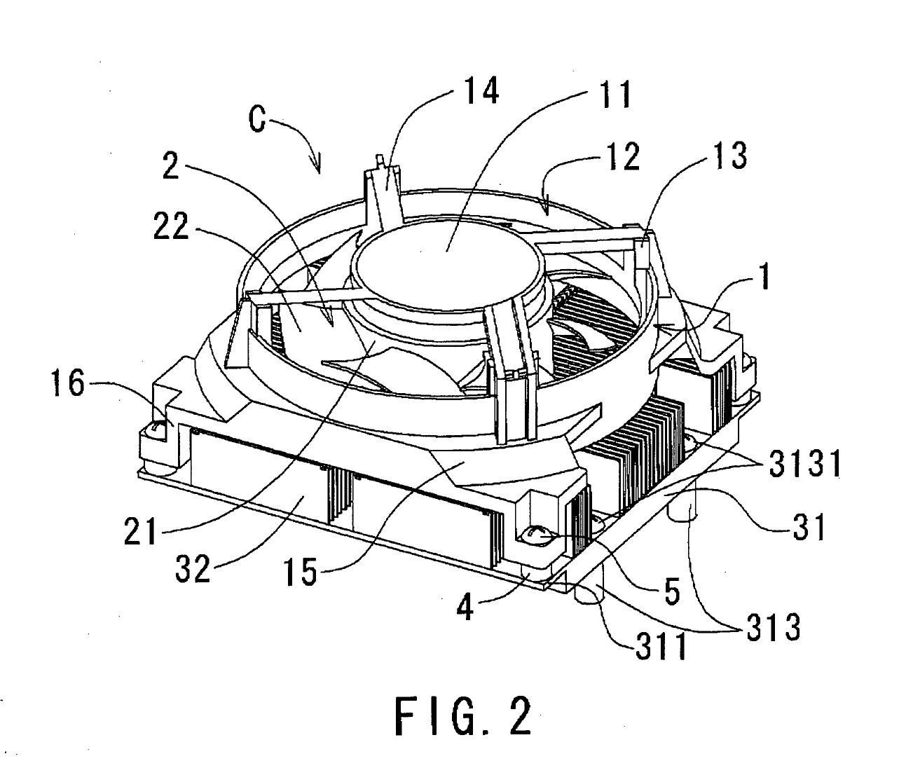

The cooling fan A of this preferred embodiment takes in air from its side on which the ribs 14 are arranged, i.e., an axially upper side in FIGS. 1 and 2. The cooling fan A then discharges the air axially downward in FIGS. 1 and 2.

A relationship of position between the surrounding wall 12 and the housing cup 11 in the axial direction can be changed by changing the height, i.e., the axial length of the supports 13. That is, a positional relationship between the surrounding wall 12 and the impeller 2 in the axial direction can be changed. The change in the positional relationship between the surrounding wall 12 and the impeller 2 changes a condition of taking air above an air-inlet side of the cooling fan A, i.e., above the surrounding wall 12. As a result, flow rate characteristics, static pressure characteristics, and noise characteristics of the cooling fan A are changed.

The height (axial length) of the respective supports 13 can be designed, considering the required characteristics of the cooling fan A. Moreover, a flow rate of an airflow flowing inside the surrounding wall 12 can be increased by reducing an inner diameter of the surrounding wall 12 in a part of the surrounding wall 12, for example. In this preferred embodiment, an axially lower part of the surrounding wall 12 has the inner diameter smaller than that of an axially upper part thereof. By designing the inner circumferential shape of the surrounding wall 12 in an appropriate manner, the flow rate characteristics, the static pressure characteristics, and the noise characteristics of the cooling fan A can be changed. Furthermore, the flow rate characteristics, the static pressure characteristics, and the noise characteristics of the cooling fan A can be also changed by changing the height (axial length) of the surrounding wall 12.

The smaller a distance between each rib 14 and a blade 22 located at an axially closest position to that rib 14 is, the louder a generated noise becomes. Therefore, in order to reduce noises generated by interference between the ribs 14 and the blades 22, the axial height of the supports 13 is set to increase the axial distance between each rib 14 and one of the blades 22 which is located at an axially closest position to that rib 14 in this preferred embodiment.

Flange portions 15 are provided on an outer circumferential surface of the surrounding wall 12 at four positions, respectively. Each flange portion 15 projects outward in the radial direction. Radially outside each flange portion 15 is arranged a support leg 16 extending downward in the axial direction. An axially lower end of each support leg 16 is provided with a screw hole 161 through which a screw 5 can be inserted in the axial direction.

Since the cooling fan A is secured to the heat sink B with the four supporting legs 16, each of the flange portions 15 and supporting legs 16 has to have a sufficient level of strength against an external force such as bending moment. Thus, a reinforcing rib (not shown) is formed axially below the flange portion 15, thereby improving strength against an impact when a load is applied to the supporting leg 16.

The screw hole 161 is uncovered because the cooling fan A is screwed to the heat sink B from above in the axial direction by using a screwdriver. The screw hole 161 is formed at an end of the supporting leg 16 to run through the supporting leg 16 axially.

### (2) Heat Sink Structure

The heat sink B is a member which dissipates heat and is made of material having relatively high thermal conductivity, such as aluminum, copper, or copper alloy. It is preferable that the material for the heat sink B have a thermal conductivity of 200 W/(m·k) or more. For example, aluminum and copper have thermal conductivities of 236 W/(m·k) and 390 W/(m·k) at a room temperature, respectively.

The heat sink B is usually formed to maximize an area of contact with outside air, i.e., a surface area of the heat sink B (especially, of each heat-dissipating fin 32). In this preferred embodiment, a plurality of heat-dissipating fins 32 are formed by pressing and are arranged on a base portion 31 at a regular interval, as shown in FIG. 1. Please note that no heat-dissipating fin 32 is arranged on a central portion of the base portion 31, as shown in FIG. 1.

In general, a die for use in extruding and drawing aluminum has a simpler structure and provides higher dimensional accuracy of an obtained product, as compared with a die for use for copper. When copper is used as material for a product, it is very difficult to form a complicated shape by extruding and drawing the material and dimensional accuracy of the obtained product is very bad. In other words, it is almost impossible to form a heat sink which has a complicated shape and is made of copper by extruding and drawing. For this reason, aluminum is used as material for a complicated heat sink with heat-dissipating fins integrally formed therewith. However, the thermal conductivity of copper is much higher than that of aluminum. So, if a copper heat sink having the same shape as that of an aluminum heat sink could be formed, the copper heat sink would have a higher cooling performance than the aluminum heat sink. Thus, in this preferred embodiment, the heat sink B is formed by attaching the heat-dissipating fins 32 made of copper to the base portion 31 made of copper.

In the heat sink B of this preferred embodiment, the thickness of each copper heat-dissipating fin 32 can be reduced to a level that cannot be obtained by extruding. Such thin heat-dissipating fins 32 are arranged on the base portion 31. Thus, an area contributing to heat dissipation can be increased. It should be noted that the material and the shape of the heat sink are not limited to those of this preferred embodiment but can be modified in various ways.

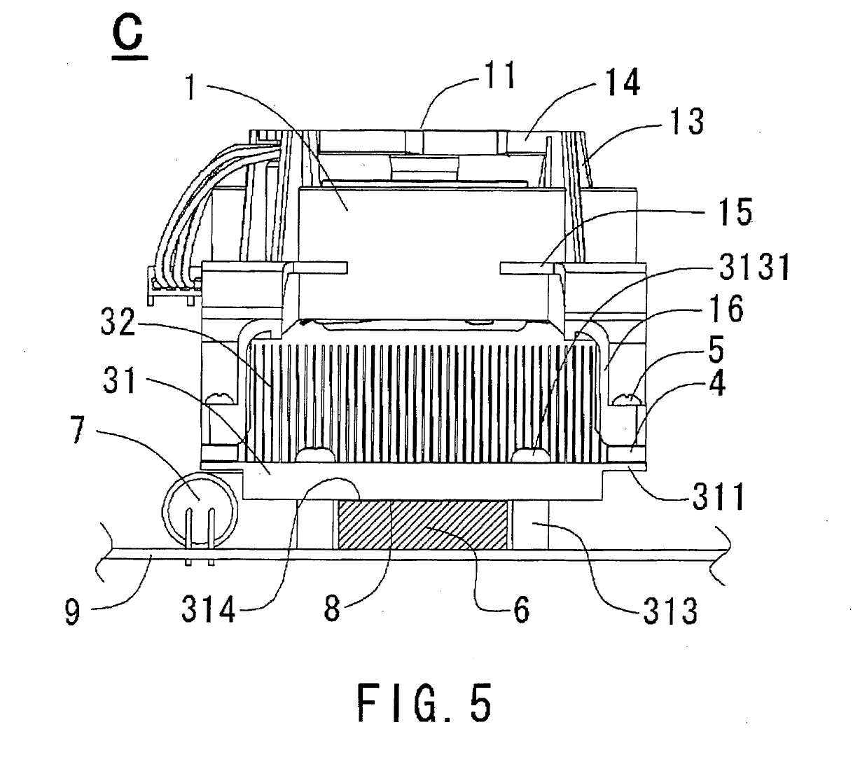

FIG. 5 is a side view showing the heat sink and fan unit C of this preferred embodiment. The heat sink and fan unit C is placed on MPU. The base portion 31 of the heat sink and fan unit C is joined at an MPU joining surface 314 to MPU 6 via a thermally conductive member or material 8 having high thermal conductivity. In this preferred embodiment, a tape-like member, e.g., a thermal tape formed by applying pressure-sensitive adhesive containing filler onto a base member to coat the base member is used as the thermally conductive member or material 8, considering workability. Examples of the base member are a polyimide film and aluminum foil.

Alternatively, thermally conductive silicone resin in the form of grease, in which powders having high thermal conductivity, e.g., alumina, are blended with silicone oil as base oil, may be used. This is because it is preferable that an area of contact between the heat conductive member or material 8, and the surface of MPU 6 and the MPU joining surface 314 of the heat sink B be large. Since the thermally conductive silicone resin is grease, it can be in close contact with both the surface of MPU 6 and the MPU joining surface 314 with almost no clearance. Any other thermally conductive member or material can be used as the member 8, as long as it has high thermal conductivity.

Referring to FIG. 1, the base portion 31 is approximately rectangular when seen from above. The base portion 31 includes reduced-thickness portions 311 at both ends in a direction perpendicular to its longitudinal direction. The thickness of the reduced-thickness portion 311 in the axial direction is thinner than that of remaining portions of the base portion 31. Heat sink securing portions 313 which secure the base portion 31 of the heat sink B and an object to be cooled to each other are provided at both the longitudinal ends of the base portion 31. Two heat sink securing portions 313 at each longitudinal end of the base portion 31. Therefore, a total of four heat sink securing portions 313 are provided.

A through hole through which a securing screw 3131 goes through is formed in each heat sink securing portion 313. When the securing screws 3131 are inserted into the associated through holes of the heat sink securing portions 313, respectively, the heat sink B is secured to the object to be cooled by screwing. Four corners of the base portion 31 are included in the aforementioned reduced-thickness portions 311. A securing hole 312 is formed at each corner. Thus, no heat-dissipating fin 32 is arranged in regions on the base portion 31 in which the heat sink securing portions 313 and the securing holes 312 are arranged, as shown in FIG. 1.

The arrangement of the reduced-thickness portions 311 and the heat sink securing portions 313 is not limited to the above. The reduced-thickness portions 311 may be arranged at both longitudinal ends, while the heat sink securing portions 313 are arranged at both ends in the direction perpendicular to the longitudinal direction of the base portion 31. It is enough that the heat sink securing portions 313 are arranged at facing sides of the base portion 31, the reduced-thickness portion 311 is arranged at either one or both of other facing sides, and the securing hole 312 is formed to extend through the reduced-thickness portion 311.

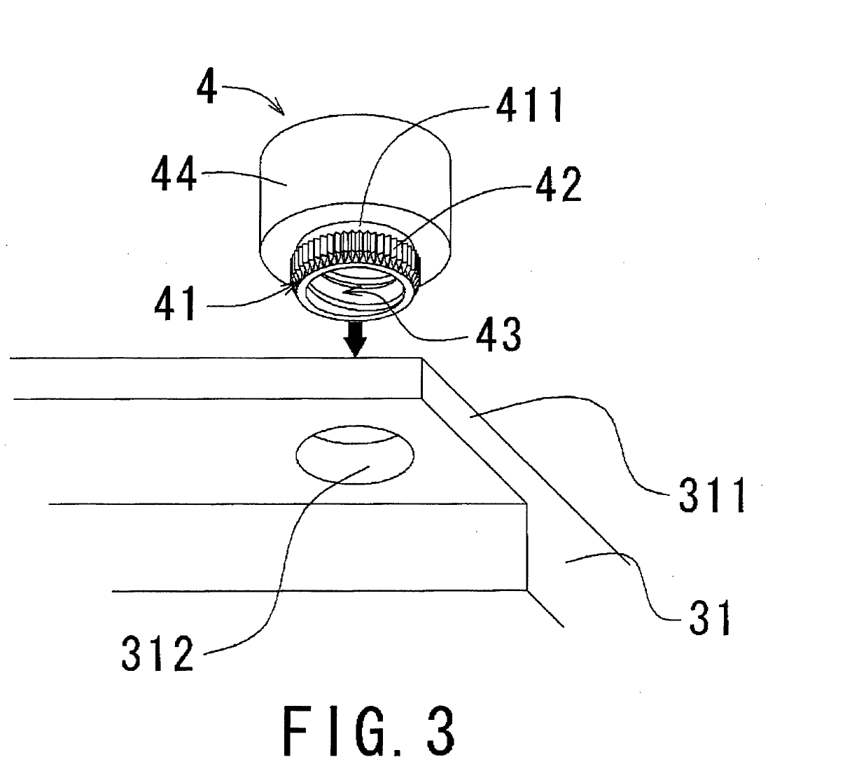

FIG. 3 is a perspective view of one securing hole 312 formed in the base portion 31 and a spacer 4. The spacer 4 is put in the securing hole 312 by interference fit. As shown in FIG. 3, the spacer 4 is hollow and cylindrical and has an internal thread 43 on its inner circumferential surface.

The spacer 4 is provided with a smaller-diameter portion 41 having an outer diameter approximately the same as an inner diameter of the securing hole 312. A plurality of raised-up portions 42 each extending in the axial direction are provided on an outer circumferential surface of the smaller-diameter portion 41 at a regular circumferential interval. The raised-up portions 42 are formed by knurling. Knurl rolling, which is conventionally used, causes plastic deformation of a surface to be knurled by imposing a pattern by rolling. On the other hand, knurl cutting, which has been used in recent years and is used in this preferred embodiment, applies less stress to an object to be processed, as compared with knurl rolling. Thus, more accurate processing can be carried out by knurl cutting.

The raised-up portions 42 are not formed in a region 411 on the outer circumferential surface of the smaller-diameter portion 41. The region 411 is a region adjacent to a larger-diameter portion 44 of the spacer 4, i.e., between the smaller-diameter portion 41 and the larger-diameter portion 44. Please note that a method for forming the raised-up portions 42 is not limited to knurling.

When the spacer 4 is inserted into the securing hole 312 by interference fit, the raised-up portions 42 on the outer circumferential surface of the smaller-diameter portion 41 embed themselves into an inner circumferential surface of the securing hole 312. That is, a structure for securing the spacer 4 to the base portion 31 is formed by interaction between a pressing force of the inner circumferential surface of the securing hole 312 acting inward in a radial direction of the securing hole 312 and a pressing force of the outer circumferential surface of the smaller-diameter portion 41 and a pressing force of the raised-up portions 42 both acting outward in the radial direction of the securing hole 312. Preferably, material which can be easily cut and has good corrosion resistance is used for the spacer 4. In this preferred embodiment, brass is used. For the base portion 31 and heat-dissipating fins 32 of the heat sink B, copper is used which has high thermal conductivity, as described above. Since hardness of brass is higher than that of copper, the raised-up portions 42 on the outer circumferential surface of the smaller-diameter portion 41 can easily embed themselves into the inner circumferential surface of the securing hole 312 when the spacer 4 is inserted into the securing hole 312 by interference fit.

Moreover, the smaller-diameter portion 41 has the region 411 where no raised-up portion 42 is formed. Thus, when the smaller-diameter portion 41 is inserted into the securing hole 312 by interference fit, edges of the raised-up portions 42 on the region 411 side are caught by the securing hole 312, so that strength of securing the spacer 4 to the securing hole 312 is enhanced. If the spacer 4 and the base portion 31 are made of the same material or the material for the base portion 31 is harder than that for the spacer 4, the raised-up portions 42 hardly embed themselves into the inner circumferential surface of the securing hole 312. This may result in insufficient strength of the securing.

The spacer 4 is inserted into the securing hole 312 by interference fit until the smaller-diameter portion 41 is completely accommodated in the securing hole 312. That is, insertion of the spacer 4 is carried out only until an end of the larger-diameter portion 44 on the smaller-diameter portion 41 side comes into contact with the base portion 31.

Moreover, since the height of the smaller-diameter portion 41 in a direction of interference fit is equal to or lower than the thickness of the reduced-thickness portion 311 in the direction of interference fit, the spacer 4 does not project from a bottom surface of the base portion 31 (i.e., a bottom surface of the reduced-thickness portion 311) after the spacer 4 is inserted into the securing hole 312. Please note that the structure for securing the spacer 4 to the base portion 31 is not limited to the above. Other securing structures, e.g., a securing structure using adhesive may be used.

(3) Structure for Fastening Cooling Fan and Heat Sink

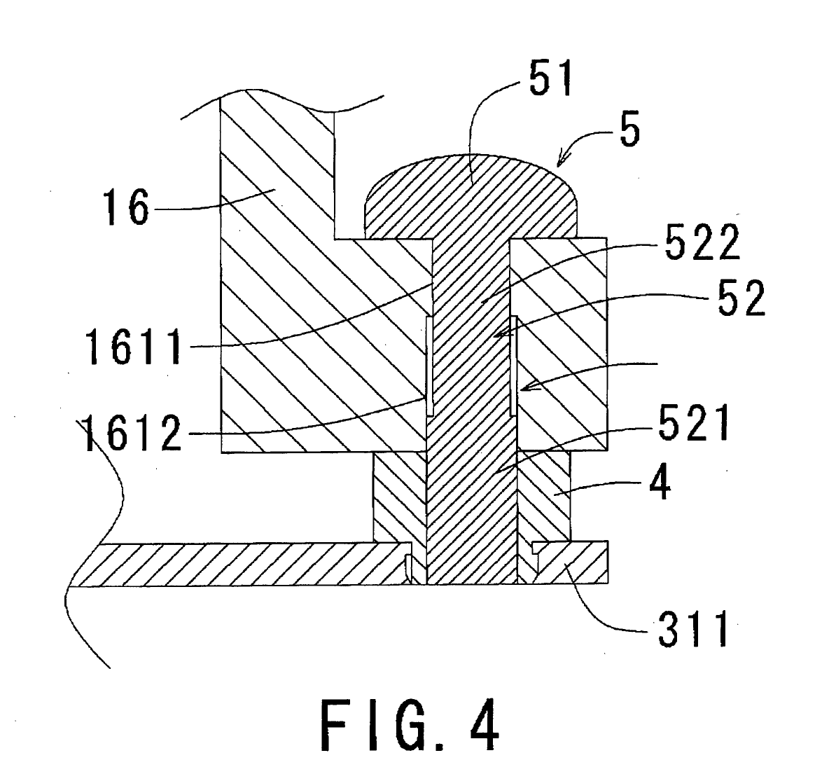

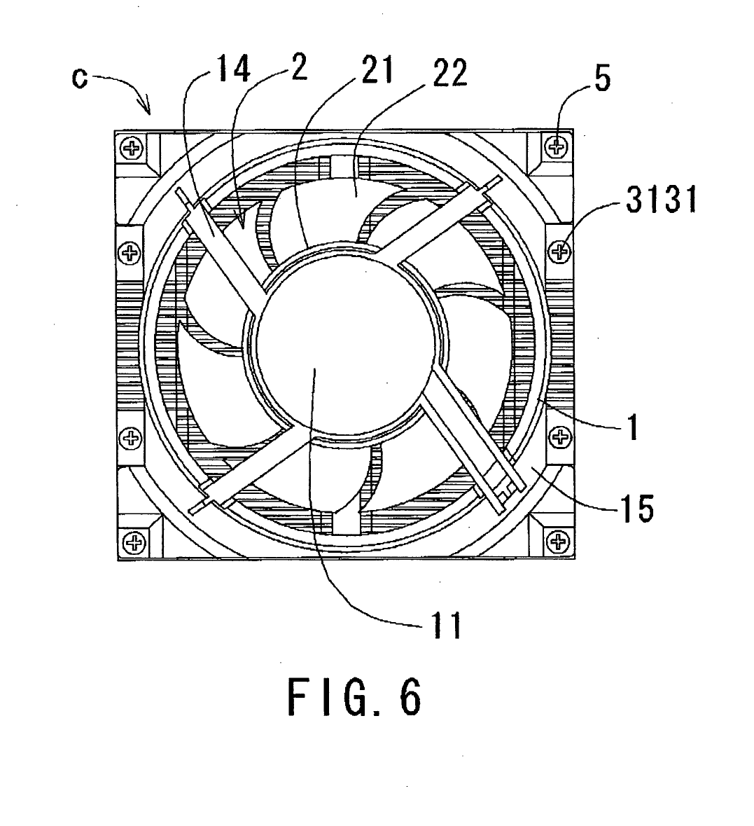

FIG. 2 is a perspective view of the heat sink and fan unit C. FIG. 4 is a cross-sectional view showing a fastening structure in which the supporting leg 16 and the base portion 31 are screwed to each other via the spacer 4 therebetween. FIG. 6 is a top view of the heat sink and fan unit C.

The cooling fan A is attached to the heat sink B from above the heat-dissipating fins 32, as shown in FIG. 1. The securing holes 312 are provided at four corners of the base portion 31 and the spacers 4 are put in the securing holes 312 by interference fit, respectively. On the spacers 4 are placed on the supporting legs 16 of the cooling fan A, respectively.

While the screw hole 161 of each supporting leg 16 is coincident with a hole defined by the inner circumferential surface of an associated one of the spacers 4 in the axial direction, a screw 5 having an external thread is inserted through the screw hole 161 toward the heat sink B. The screw 5 is screwed with the internal thread 43 formed on the inner circumferential surface of the spacer 4, thereby fastening the spacer 4 and the supporting leg 16 in the axial direction. In this manner, the cooling fan A and the heat sink B are firmly secured to each other.

The screw 5 has a head 51 at its top end. The head 51 is gripped by a screwdriver when the screw 5 is driven by the screwdriver. The head 51 has a slot to be engaged with the tip of the screwdriver on its top surface. For example, a cross-head screw has an X-shaped slot, or a slotted screw has a single slot. The screw 5 includes a threaded portion 52 formed by an externally threaded portion 521 and a portion 522 in the form of a cylindrical column. The cylindrical column portion 522 is arranged on the head 51 side of the externally threaded portion 521, i.e., between the head 51 and the externally threaded portion 521. No thread is formed on an outer circumference of the cylindrical column portion 522. An outer diameter of the cylindrical column portion 522 is smaller than an outer diameter of the externally threaded portion 521.

The screw hole 161 includes a smaller-diameter portion 1611 and a larger-diameter portion 1612. The smaller-diameter portion 1611 is arranged in a part of the screw hole 161 from which the screw 5 is inserted into the screw hole 161, i.e., an upper part of the screw hole 161 in FIG. 4, and has an inner diameter smaller than the outer diameter of the externally threaded portion 521 and larger than the outer diameter of the cylindrical column portion 522. The larger-diameter portion 1612 is arranged on a heat sink B side of the smaller-diameter portion 1611, i.e., in a lower part of the screw hole 161 in FIG. 4, and has an inner diameter larger than the outer diameter of the externally threaded portion 521.

The screw 5 is inserted into the cooling fan A prior to screwing the cooling fan A to the heat sink B. The reason for this is now described.

The inner diameter of the smaller-diameter portion 1611 of the screw hole 16 is smaller than the outer diameter of the external thread portion 521 of the screw 5. So, it is impossible to insert the screw 5 into the screw hole 161 only by pushing the screw 5 toward the inside of the screw hole 161. Instead, it is necessary to drive the screw 5 with a screwdriver and insert the screw 5 while making the external thread of the externally threaded portion 521 tap on the inner circumferential surface of the smaller-diameter portion 1611. After tapping is finished, the externally threaded portion 521 passes through the smaller-diameter portion 1611 and arrives at a position at which the externally threaded portion 521 faces the larger-diameter portion 1612 in the radial direction. In this state, the smaller-diameter portion 1611 is arranged between the head 51 and the externally threaded portion 521. Thus, if the screw 5 is further moved forward in a direction of insertion thereof, the head 51 comes into contact with a screw insertion opening of the screw hole 161, thereby preventing further movement of the screw 5. On the other hand, if the screw 5 is moved in an opposite direction to the direction of insertion of the screw 5, the smaller-diameter portion 1611 and the externally threaded portion 521 come into contact with each other, thereby preventing further movement of the screw 5. In this manner, the screw 5 cannot be detached from the screw hole 161.

Since the axial length of the small-diameter portion 1611 of the screw hole 16 is shorter than the axial length of the cylindrical column portion 522 of the screw 5, the screw 5 can play inside the screw hole 161, i.e., can move by a distance equal to a difference in the axial length between the cylindrical column portion 522 and the smaller-diameter portion 1611. Thus, when the cooling fan A is detached from the heat sink B, the screw 5 cannot be easily detached from the screw hole 161. So, it is possible to prevent fall of the screw 5 on another electronic component and possible short circuit caused by the fallen screw 5. Moreover, it is unlikely that the screw 5 is lost. Accordingly, an individual PC user can detach the cooling fan A from the heat sink B easily.

The head 51 is formed to have a larger diameter than the cylindrical column portion 52. When the supporting leg 16 and the spacer 4 are secured to each other by screwing, the screw 5 is driven by a screwdriver until an upper end face of a portion of the supporting leg 16 where the screw hole 16 is arranged comes into contact with a lower surface of the head 51. The lower surface of the head 51 is a closest surface of the head 51 to the external thread of the screw 5. The screw 5 is designed to have such a dimension that the cylindrical column portion 52 of the screw 5, which is provided with the external thread, does not project from a lower end face of the spacer 4. In other words, the cylindrical column portion 52 does not project from a lower end face of the reduced-thickness portion 311 of the base portion 31.

Since the heat sink B is made of copper, it may weigh about 1 kg. Thus, the cooling fan A and the heat sink B have to be fastened to each other with high securing strength. According to the aforementioned fastening method using the screw 5 of this preferred embodiment, the cooling fan A and the heat sink B are surely fastened to each other. In addition, after the heat sink B is placed on MPU 6, the top surface of the screw 5 is not uncovered and can be seen from above the heat sink and fan unit C, as shown in FIGS. 2 and 6. Thus, the screw 5 can be driven by a screwdriver to loose fastening by screwing even after the heat sink B is placed on MPU 6. This allows the cooling fan A to be easily detached from the heat sink B irrespective of the presence of an electronic part mounted near MPU 6. On the other hand, when a conventional securing method is used for securing a heat sink and a cooling fan to each other, the cooling fan cannot be detached from the heat sink easily if there is any electronic part mounted near the heat sink and fan unit.

Many electronic parts are mounted around a location at which the heat sink and fan unit C is placed. The size of a circuit board (mother board) 9 in an electronic device has continued to be reduced with recent demands for size reduction of the electronic device itself. In the heat sink and fan unit C of this preferred embodiment, it is possible to mount an electronic part 7 under the reduced-thickness portion 311 of the heat sink B, as shown in FIG. 5. The reduced-thickness portion 311 is formed to have such a thickness that a relatively large electronic part 7, e.g., an electrolytic capacitor, can be mounted under the reduced-thickness portion 311. Moreover, the spacer 4 and the screw 5 do not project from the lower end face of the reduced-thickness portion 311, as described above. Thus, it is possible to make the most of a space under the reduced-thickness portion 311 for mounting the electronic part 7 in this preferred embodiment. That is, since the base portion 31 is provided with the reduced-thickness portion 311, many electronic parts can be mounted efficiently.

In the structure for fastening the cooling fan A and the heat sink B to each other of this preferred embodiment, the supporting legs 16 and the spacers 4 are fastened to each other with the screws 5, respectively. In contrast, if no spacer 4 is used, the supporting legs 16 are fastened to the reduced-thickness portion 311 with the screws 5. However, since the reduced-thickness portions 311 are thinner than other portions of the base portion 31, it is not possible to ensure a sufficient dimension for forming an internal thread to be screwed with the screw 5 in the axial direction.

In order to obtain the sufficient dimension, the thickness of the reduced-thickness portion 311 has to be increased, or the thickness of the entire base portion 31 has to be increased upward in the axial direction. In the former case, no electronic part can be arranged under the portions 311. In the latter case, the following problem arises. Dimensions of the heat sink and fan unit C including its axial height are specifically determined in order to be mounted in a casing of an electronic device. Thus, the heat sink and fan unit C has to be designed to provide a better cooling performance while having dimensions not larger than the specified dimensions. If the thickness of the entire base portion 31 is increased, the axial height of the heat-dissipating fins 32 should be reduced to cancel out the increase in the thickness of the base portion 31. This results in reduction in an area contributing to heat dissipation of the heat sink B, lowering the cooling performance of the heat sink B. Furthermore, because of a relatively low level of hardness of copper, a sufficient fastening strength cannot be obtained only by fastening the supporting legs 16 to the base portion 31 by screwing.

According to the preferred embodiment of the present invention, the heat sink B having a thin base portion 31 and the cooling fan A are fastened to each other via the spacers 4. Therefore, a high level of fastening strength can be achieved.

In the aforementioned preferred embodiment, the base portion 31 of the heat sink B is an approximately rectangular. However, the shape of the base portion 31 is not limited thereto. For example, the base portion 31 may be square. The base portion 31 can be tetragonal, as long as the reduced-thickness portion 311 is formed at either one or both of facing sides of the tetragon, the heat sink securing portions 313 are formed at other facing sides, and each securing hole 312 is formed to extend trough the reduced-thickness portion 311.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A heat sink and fan unit comprising:
a heat sink having a plurality of heat-dissipating fins;
a cooling fan generating a current of a cooling air toward the heat sink and including a supporting leg which extends toward the heat sink, wherein
the supporting leg is screwed to the heat sink with a screw inserted into the supporting leg toward the heat sink, to secure the cooling fan to the heat sink.

2. The heat sink and fan unit according to claim 1, wherein the supporting leg is provided at its top end with a through hole into which the screw is inserted toward the heat sink, the through hole including a larger-diameter portion and a smaller-diameter portion which have a larger inner diameter and a smaller inner diameter, respectively, the larger-diameter portion being closer to the heat sink than the smaller-diameter portion,
the screw includes an externally threaded portion, a head portion having a larger outer diameter than an outer diameter of the externally threaded portion, and a cylindrical-column portion arranged between the external thread portion and the head portion and having no thread,
the cylindrical column portion has an outer diameter smaller than an outer diameter of the smaller-diameter portion of the through hole, and the externally threaded portion has the outer diameter between those of the smaller-diameter portion and the larger-diameter portion of the through hole, and
the smaller-diameter portion of the through hole is arranged between the head portion and the externally threaded portion of the screw to prevent detachment of the screw when the cooling fan is detached from the heat sink.

3. The heat sink and fan unit according to claim 1, wherein the heat sink includes a base portion on which the plurality of heat-dissipating fins are arranged, and the cooling fan is attached to the base portion with the plurality of heat-dissipating fins arranged between the cooling fan and the base portion.

4. The heat sink and fan unit according to claim 3, further comprising a hollow, cylindrical spacer arranged between the supporting leg and the heat sink, wherein
the cooling fan is secured to the heat sink by being screwed at the supporting leg to the heat sink via the spacer.

5. The heat sink and fan unit according to claim 4, wherein the base portion is provided with a securing hole into which the spacer is to be fitted and secured, and the spacer is provided on its outer surface with a smaller-diameter portion fitted into the securing hole, the smaller-diameter portion having a smaller outer diameter than that of other portions of the spacer.

6. The heat sink and fan unit according to claim 5, wherein the spacer has hardness higher than that of the base portion, and the smaller-diameter portion of the spacer is provided on its outer surface with a plurality of raised-up portions that are raised outward in a radial direction of the spacer.

7. The heat sink and fan unit according to claim 6, wherein the plurality of raised-up portions are knurled portions.

8. The heat sink and fan unit according to claim 4, wherein an inner surface of the spacer has an internal thread to be screwed with the screw.

9. The heat sink and fan unit according to claim 4, wherein the spacer is made of metal.

10. The heat sink and fan unit according to claim 4, wherein the base portion is approximately tetragonal and has four corners respectively having four securing holes formed therein, respectively, and
the cooling fan includes four supporting legs respectively corresponding to the four securing holes.

11. The heat sink and fan unit according to claim 10, wherein the base portion includes a reduced-thickness portion at least one of facing sides of the base portion, and
the securing holes are formed in the reduced-thickness portion.

12. The heat sink and fan unit according to claim 10, wherein the base portion includes reduced-thickness portions at its opposite ends, respectively, the reduced-thickness portions containing the four corners of the base portion, and
the securing holes are formed in the reduced-thickness portion.

13. The heat sink and fan unit according to claim 3, wherein the base portion and the heat-dissipating fins are made of copper.

14. The heat sink and fan unit according to claim 3, wherein the base portion and the heat-dissipating fins are made of copper alloy.
